(19) United States
(12) Patent Application Publication
(10) Pub. No.: US 2013/0248229 A1
(43) Pub. Date: Sep. 26, 2013

(54) ELECTRICAL CONDUCTORS AND METHODS OF MANUFACTURING ELECTRICAL CONDUCTORS

(71) Applicant: TYCO ELECTRONICS CORPORATION, Berwyn, PA (US)

(72) Inventor: Rodney I. Martens, Mechanicsburg, PA (US)

(73) Assignee: Tyco Electronics Corporation, Berwyn, PA (US)

(21) Appl. No.: 13/759,806

(22) Filed: Feb. 5, 2013

Related U.S. Application Data
(60) Provisional application No. 61/613,650, filed on Mar. 21, 2012.

(51) Int. Cl. H01B 13/00; H05K 1/05

(52) U.S. Cl. CPC H01B 13/00; H05K 1/056
USPC 174/255; 156/60; 156/306.3; 156/280; 156/182; 228/115; 228/203; 219/121.63

(57) ABSTRACT

An electrical conductor includes a base substrate of at least one of copper, copper alloy, nickel or nickel alloy and a layered structure applied to the base substrate. The layered structure includes a foil and a graphene layer deposited on the foil. The layered structure is applied to the base substrate after the graphene layer is deposited on the foil. A method of manufacturing the electrical conductor includes providing a base substrate, providing a foil, depositing a graphene layer on the foil to define a layered structure, and depositing the layered structure on the base substrate.

### CROSS REFERENCE TO RELATED APPLICATIONS

This application claims the benefit of U.S. Provisional Application No. 61/613,650 tiled Mar. 21, 2012, the subject matter of which is herein incorporated by reference in its entirety.

### BACKGROUND OF THE INVENTION

The subject matter herein relates generally to electrical conductors and methods of manufacturing electrical conductors.

Electrical conductors have many forms, such as a contact, a terminal, a spring contact, a pin, a socket, an eye-of-needle pin, a micro-action pin, a compliant pin, a wire, a cable braid, a trace, a pad and the like. Such electrical conductors are used in many different types of products or devices, including electrical connectors, cables, printed circuit boards, and the like. The metals used in the electrical conductors are susceptible to corrosion, diffusion or other reactions, limiting their use or requiring protective coatings. For example, when copper or copper alloy electrical conductors are used, such conductors are susceptible to corrosion. A gold layer is typically applied to the copper as a corrosion inhibitor. However, the gold and copper materials suffer from diffusion and typically a diffusion barrier, such as nickel is deposited between the copper and gold layers.

Corrosion of base metals is detrimental to the conductor interface and signal integrity. Current plating methods used to mitigate corrosion often leave a porous surface, resulting in oxidation and corrosion of the underlying surface. Additionally, some layered structures suffer from problems associated with friction, stiction and other contact forces, limiting application of the conductors.

Some known conductors use graphene or other carbon based structures as barriers for the conductors. However, application of the graphene to the conductors is problematic. One known method of applying graphene to the conductor includes depositing the graphene in a chemical vapor deposition (CVD) process. However, such processes use very high temperatures. Subjecting the conductor to such high temperatures may be damaging to the conductor. For example, typical conductors use copper alloys having melting point temperatures that are below the temperatures desired for the CVD process. Subjecting such conductors to the CVD process will cause grain boundaries, triple points and other problems with the conductors.

A need remains for an electrical conductor that addresses the aforementioned problems and other shortcomings associated with traditional electrical conductors.

### BRIEF DESCRIPTION OF THE INVENTION

In one embodiment, a method of manufacturing an electrical conductor is provided including providing a base substrate, providing a foil, depositing a graphene layer on the foil to define a layered structure, and depositing the layered structure on the base substrate.

Optionally, the graphene layer may be deposited directly on the foil. The foil may be deposited directly on the base substrate. Depositing the layered structure may include cladding the foil to the base substrate. Depositing the layered structure may include at least one of pressure bonding, rolling, cold welding, laser bonding, or soldering the foil to the base substrate.

Optionally, the method may include plating the graphene layer with a surface layer. The base substrate may include a base and a barrier deposited on the base. The layered structure may be deposited on the barrier. The graphene layer may be deposited on the foil prior to the foil being deposited on the base substrate.

Optionally, depositing the graphene layer may include depositing graphene on one or more surfaces of the foil by processing the electrical conductor using a chemical vapor deposition process using an organic compound precursor and heat of sufficient temperature to facilitate graphene growth on the metal compound comprising the foil. Optionally, the base substrate is not subjected to the heat of the chemical vapor deposition process. The graphene layer may be deposited by the chemical vapor deposition process prior to the foil being deposited on the base substrate.

In another embodiment, an electrical conductor is provided having a base substrate of at least one of copper, copper alloy, nickel or nickel alloy and a layered structure applied to the base substrate. The layered structure includes a foil and a graphene layer deposited on the foil. The layered structure is applied to the base substrate after the graphene layer is deposited on the foil.

Optionally, the graphene layer may be deposited directly on the foil. The foil may be deposited directly on the base substrate. The foil may be clad to the base substrate. The foil may be at least one of pressure bonded, pressure rolled, cold welded, laser bonded, and soldered to the base substrate.

Optionally, the electrical conductor may include a surface layer on the graphene layer opposite the foil. The surface layer may be plated on the graphene layer opposite the foil. The base substrate and layered structure may be stamped and formed after the layered structure is deposited on the base substrate. The base substrate may include a base and a barrier with the layered structure being deposited on the barrier.

Optionally, the graphene layer may be CVD deposited on one or more surfaces of the foil using an organic compound precursor and heat of sufficient temperature to facilitate graphene growth on the metal compound comprising the foil. The graphene layer may be deposited prior to the foil being deposited on the base substrate.

### BRIEF DESCRIPTION OF THE DRAWINGS

FIG. 1 is a cross sectional view of a portion of an electrical conductor formed in accordance with an exemplary embodiment.

FIG. 2 illustrates a conductor formation system used to form electrical conductors, such as the electrical conductor shown in FIG. 1.

FIG. 3 is a flow chart showing an exemplary method of manufacture of an electrical conductor, such as the electrical conductor shown in FIG. 1.

### DETAILED DESCRIPTION OF THE INVENTION

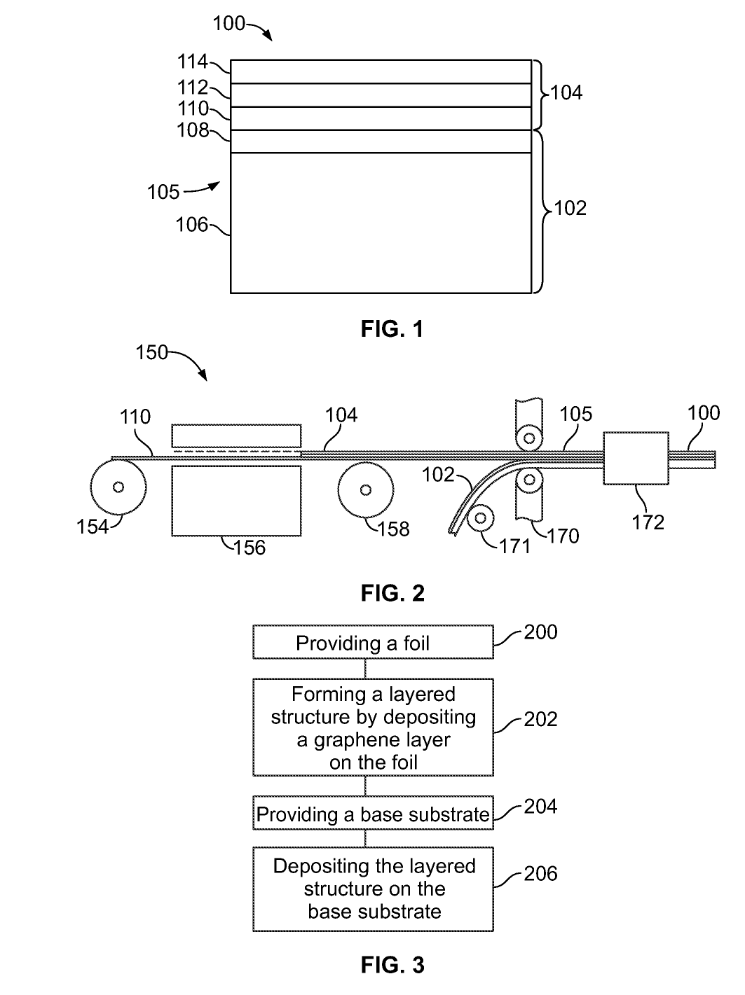

FIG. 1 is a cross sectional view of a portion of an electrical conductor 100 formed in accordance with an exemplary embodiment. The electrical conductor 100 may be any type of electrical conductor, such as a contact, a terminal, a spring contact, a pin, a socket, an eye-of-the-needle pin, a micro-action pin, a compliant pin, a wire, a cable braid, a trace, a pad and the like. The electrical conductor 100 may form part of an electrical connector, a cable, a printed circuit board and the like.

In an exemplary embodiment, the electrical conductor 100 is a multi-layered structure having a base substrate 102 and a layered structure 104 that together define a workpiece 105. Optionally, layered structures 104 may be applied to both sides of the base substrate 102 to from a workpiece. The workpiece 105 is processed to form the conductor 100. For example, the workpiece 105 may be plated, stamped, formed, and the like. The layered structure(s) 104 may be a surface layered structure 104 at an outer surface of the electrical conductor 100.

The layered structure 104 provides a corrosion-resistant electrically conductive layer on the base substrate 102. In an exemplary embodiment, the layered structure 104 includes a conductive foil layer 110 (may be referred to hereinafter as conductive foil 110 or just foil 110), a graphene layer 112 and a conductive surface layer 114. The layered structure 104 may just include the foil 110 and the graphene layer without the surface layer 114 in some embodiments. The foil 110 may be a strip or other stock metal component. The foil 110 may be a copper or copper alloy, a nickel or nickel alloy or another suitable metal. The foil 110 is used to support the graphene layer 112, such as for application to the base substrate 102 during a later process. The graphene layer 112 includes a graphene deposit or other carbon based barrier to inhibit corrosion and/or enhance other characteristics of the electrical conductor 100, such as the friction coefficient, conductivity and the like. The surface layer 114 is a non-carbon based layer(s), such as metal plating such as gold, silver, tin, palladium, nickel, palladium-nickel, platinum and the like. The surface layer 114 may be used to inhibit corrosion or enhance other characteristics of the electrical conductor 100, such as wear resistance, coefficient of friction and the like.

The layered structure 104 is generally a thin layer as compared to the base substrate 102. The layered structure 104 may be deposited on the base substrate 102 by any known process, such as cladding, laminating, adhering, bonding or other suitable process. Optionally, the layered structure 104 may be deposited directly on the underlying base substrate 102. Alternatively, one or more other layers may be provided between the layered structure 104 and the base substrate 102. In an exemplary embodiment, the graphene layer 112 is deposited on the foil 110 to define the layered structure 104, which is applied to the base substrate 102 during a different process. The surface layer 114 may be applied to the layered structure 104 after the layered structure 104 is applied to the base substrate 102.

The base substrate 102 may be a multi-layered structure. In the illustrated embodiment, the base substrate 102 includes a base 106 and a barrier 108 deposited on the base 106. Optionally, the base 106 and/or the barrier 108 may be a multi-layered structure. The layered structure 104 and the base substrates 102 together define a stackup of layers. The base substrate 102 may only include the base 106 without the barrier 108, with the layered structure 104 applied directly to the base 106 as opposed to the barrier 108.

In an exemplary embodiment, the base 106 is electrically conductive and includes a metal compound, such as a copper or a copper alloy. Other metal compounds for the base 106 may include nickel, nickel alloy, steel, steel alloy, aluminum, aluminum alloy, palladium-nickel, tin, tin alloy, cobalt, carbon, graphite, graphene, carbon-based fabric, or any other conductive material. The barrier 108 is electrically conductive and includes a metal compound, such as nickel or a nickel alloy. Other metal compounds for the barrier 108 include other metal or conductive material such as copper, gold, silver, cobalt, tungsten, platinum, palladium, or alloys of such. The barrier 108 may provide a diffusion barrier between the base 106 and the layered structure 104, such as when copper and gold or other metal compounds that have diffusion problems are used. The barrier 108 provides a mechanical backing for application of the layered structure 104, which may be relatively thin, improving its wear resistance. The barrier 108 may reduce the impact of pores and corrosion problems if present in the layered structure 104. The barrier 108 may be deposited on the base 106 by any known process, such as plating. Optionally, the barrier 108 may be deposited directly on the underlying base 106. Alternatively, one or more other layers may be provided between the barrier 108 and the base 106, such as a graphene layer.

In an exemplary embodiment, the graphene layer 112 is used to inhibit corrosion. The graphene layer 112 may be electrically conductive. The graphene layer 112 is deposited on the foil 110. In an exemplary embodiment, the graphene layer 112 is grown on the exposed portion of the foil 110. For example, the foil 110 is processed to grow the graphene layer 112 on one or more surfaces of the foil 110 (or in select locations on the foil 110). The graphene layer 112 may cover the entire upper surface of the foil 110.

In an exemplary embodiment, the graphene layer 112 may be formed during a chemical vapor deposition (CVD) process in the presence of an organic compound, such as gaseous methane, at a high temperature, such as approximately 800° C. or higher. Deposition mechanisms may also include electron beam, microwave or other process within the vaporous atmosphere. Other processes may be used to deposit the graphene layer 112, such as laser deposition, plasma deposition or other techniques or processes. Optionally, the graphene layer 112 may be 1 atomic layer thick on the foil 110. Alternatively, the graphene layer 112 may be thicker. The graphene layer 112 provides corrosion resistance.

The graphene layer 112 may be deposited only on the exposed portions of the foil 110. For example, the metal compound of the foil 110 may be used as a catalyst during the CVD process (or other process) to promote graphene growth at the interface with the foil 110. Optionally, the CVD process may be controlled to promote graphene growth at such interface, such as by using a suitable organic precursor and processing at a suitable temperature to enhance graphene growth depending on the chemical composition (e.g. metal or metal alloy) of the foil 110. For example, the type of organic compound or gas precursor used, the pressure of the gas precursor used, the flow rate of the gas precursor, the temperature of the process, or other factors may promote graphene growth on one metal as compared to other metals.

The graphene layer 112 operates as a corrosion barrier for the electrical conductor 100 by providing a barrier between the base 106 and the environment to inhibit oxygen atoms from interacting with the metal compounds of the base 106. The graphene layer 112 may operate as a diffusion barrier to inhibit diffusion between the base 106 and the surface layer 114. Optionally, the graphene layer 112 may replace the barrier 108, acting as the diffusion barrier between the base 106 and the surface layer 114.

Optionally, the graphene layer 112 may be the outermost layer of the electrical conductor 100. The graphene layer 112 may reduce friction on the outermost surface of the electrical conductor 100, which may make mating of the electrical conductor 100 easier. The graphene layer 112 may reduce stiction of the layered structure 104. The reduction in stiction may allow use of the electrical conductor 100 in fields or devices that previously were unsuitable for electrical conductors 100 having problems with stiction and/or cold welds, such as electrical conductors having the outermost layer being a gold layer. For example, in microelectromechanical systems (MEMS) switches, stiction is a problem when a gold layer is the outermost layer of the electrical conductor.

Having the graphene layer already deposited on the foil in a prior process allows the electrical conductor to be manufactured without having to subject the base substrate to the high temperatures associated with depositing the graphene layer on the foil. For example, the base substrate may be made from a copper alloy having a melting temperature similar to or lower than the temperature needed to effectively promote graphene growth on the foil. Having only the foil, as opposed to the base substrate, transferred through the coating station or other station that deposits the graphene, benefits the electrical conductor 100, such as by reducing the risk of forming grain boundaries, triple points or pores in the base substrate. Additionally, by not having to process the base substrate through the coating station, the coating station may be operated at a higher temperature than if the base substrate were to be passed through the coating station.

In an exemplary embodiment, the foil is made from a material having a higher melting temperature than the base substrate. The foil can withstand higher temperatures than the base substrate without damaging the structure thereof. The foil may be made from a material having a higher melting temperature than the temperature desired for graphene growth and/or deposition. The base substrate may have different characteristics from the foil other than a different melting point temperature, making use of such base substrate desirable to use as opposed to a base substrate of the same material as the foil or of a material having a high enough melting point temperature to withstand the coating station and graphene growth. For example, the base substrate may have better spring characteristics than the material of the foil. The base substrate may be stronger or tougher than the material of the foil. The base substrate may have a finer grain than the material of the foil. The base substrate may have a lower cost than the material of the foil. The base substrate may be more ductile or have better forming characteristics than the material of the foil. The base substrate may have better electrical conductivity than the material of the foil. Other characteristics may be important to the selection of the particular base substrate having the lower melting point temperature. Separating the graphene growth onto a foil separate from the base substrate allows the graphene deposition and/or growth to be tailored to the application.

FIG. 2 illustrates a conductor formation system 150 used to form electrical conductors, such as the electrical conductor 100. The system 150 includes a plurality of stations that perform operations or functions on materials to form the electrical conductor 100. In the illustrated embodiment, the system 150 is an in-line system that progressively feeds product, such as strips or reels of material, through the stations to process the materials to form the electrical conductor 100. For example, the product may be continuously feed to stations for processing. In an exemplary embodiment, the system 150 is a reel system that winds and/or unwinds material from reels to progressively process the electrical conductor 100 through the system 150.

The system 150 includes a strip reel 154, on which the foil 110 is wound in strip form. The foil 110 is continuously unwound and pulled through the system 150 from the strip reel 154. The conductive foil 110 is used to form the foil 110 (shown in FIG. 1). The width of the copper foil may be dependent on the width and shape for the electrical conductor 100, which may be stamped, bent or formed to form the final product.

The system 150 includes a coating station 156. The coating station 156 applies the graphene layer 112 to the conductive foil 110. The product exiting the coating station 156 defines the layered structure 104. The graphene layer 112 may be applied in a suitable manner, such as by a CVD process. The graphene layer 112 may be grown on the foil 110 as the foil 110 passes through the coating station 156. The graphene layer 112 may be applied by other coating processes or processes other than coating.

A transfer device 158 is used to advance the layered structure 104 through the system 150. Optionally, the transfer device 158 may be one or more reels upon which the layered structure 104 is wound and/or unwound. The transfer device 158 may be a conveyor, such as a conveyor belt or roll. The foil 110 is used to support the graphene layer 112 for advancing the graphene layer 112 through the system 150. The graphene layer 112 remains applied to the foil 110 and the foil 110 is attached to the substrate 102 and forms part of the final product. Alternatively, the foil 110 may be later removed from the layered structure 104 to allow the graphene layer 112 to be attached directly to the substrate 102.

The layered structure 104 is progressively transferred through a substrate application station 170. The substrate 102 is provided on a substrate reel 171. The substrate 102 is unwound from the reel and progressively presented to the substrate application station 170 for attaching the substrate 102 to the layered structure 104. The substrate 102 may be advanced by a device other than a reel in alternative embodiments. Once the layered structure 104 is attached to the substrate 102, the layered structure 104 may be advanced through the system 150 on the substrate 102.

At the substrate application station 170, the layered structure 104 is applied to the substrate 102. The layered structure 104 may be applied to the substrate 102 by cladding the foil 110 and the substrate 102. The layered structure 104 may be applied to the substrate 102 by other processes, such as pressure bonding, rolling, cold welding, laser bonding, soldering or other processes.

The product is passed to a processing station 172 where the electrical conductor 100 may be processed, such as to enhance certain characteristics of the electrical conductor 100. For example, the processing station 172 may include a plating sub-station where the layered structure 104 is plated with the surface layer 114. The processing station 172 may include a stamping sub-station where the electrical conductors 100 are shaped and/or singulated. The processing station 172 may include a forming sub-station where the electrical conductors 100 are bent and formed into a final shape.

FIG. 3 is a flow chart showing an exemplary method of manufacture of an electrical conductor, such as the electrical conductor 100. The method includes providing 200 a foil, such as the foil 110. The foil may be a copper or copper alloy layer.

The method includes forming 202 a graphene layer, such as the graphene layer 112, on the foil to form a layered structure. The graphene layer may be formed by a CVD process or another process. The graphene layer may completely cover the foil or may selectively cover portions of the foil. The graphene layer may be formed by growing or depositing one or more graphene layers on the foil. The metal of the foil may act as a catalyst to promote selective growth of the graphene thereon.

The method includes providing 204 a base substrate, such as the base substrate 102. The base substrate may be a layered structure. The base substrate may include a base and a barrier deposited on the base, such as by plating.

The method includes depositing 206 the layered structure, such as the layered structure 104, on the base substrate. The layered structure may be directly deposited on the base substrate. For example, the foil may be clad or otherwise joined to the base substrate. Having the graphene layer already deposited on the foil in a prior process allows the electrical conductor to be manufactured without having to subject the base substrate to the high temperatures associated with depositing the graphene layer on the foil.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means plus-function format and are not intended to be interpreted based on 35 U.S.C. §112, sixth paragraph, unless and until such claim limitations expressly use the phrase “means for” followed by a statement of function void of further structure.

What is claimed is:

1. A method of manufacturing an electrical conductor, the method comprising:
providing a base substrate;
providing a foil;
depositing a graphene layer on the foil to define a layered structure; and
depositing the layered structure on the base substrate.

2. The method of claim 1, wherein the graphene layer is deposited directly on the foil.

3. The method of claim I, wherein the foil is deposited directly on the base substrate.

4. The method of claim 1, wherein said depositing the layered structure comprises cladding the foil to the base substrate.

5. The method of claim 1, wherein said depositing the layered structure comprises at least one of pressure bonding, rolling, cold welding, laser bonding, and soldering the foil to the base substrate.

6. The method of claim 1, further comprising plating the graphene layer with a surface layer.

7. The method of claim 1, wherein the base substrate includes a base and a barrier deposited on the base, the layered structure being deposited on the barrier.

8. The method of claim 1, wherein the graphene layer is deposited on the foil prior to the foil being deposited on the base substrate.

9. The method of claim 1, wherein said depositing a graphene layer comprises depositing graphene on one or more surfaces of the foil by processing the electrical conductor using a chemical vapor deposition process using an organic compound precursor and heat of sufficient temperature to facilitate graphene growth on the metal compound comprising the foil, the base substrate not being subjected to the heat of the chemical vapor deposition process.

10. The method of claim 1, wherein said depositing a graphene layer comprises depositing graphene on one or more surfaces of the foil by processing the electrical conductor using a chemical vapor deposition process using an organic compound precursor and heat of sufficient temperature to facilitate graphene growth on the metal compound comprising the foil, the graphene layer being deposited by the chemical vapor deposition process prior to the foil being deposited on the base substrate.

11. An electrical conductor comprising:
a base substrate of at least one of copper, copper alloy, nickel or nickel alloy;
a layered structure applied to the base substrate, the layered structure comprising a foil and a graphene layer deposited on the foil, the layered structure being applied to the base substrate after the graphene layer is deposited on the foil.

12. The electrical conductor of claim 11, wherein the graphene layer is deposited directly on the foil.

13. The electrical conductor of claim 11, wherein the foil is deposited directly on the base substrate.

14. The electrical conductor of claim 11, wherein the foil is clad to the base substrate.

15. The electrical conductor of claim 11, wherein the foil is at least one of pressure bonded, pressure rolled, cold welded, laser bonded, and soldered to the base substrate.

16. The electrical conductor of claim 11, further comprising a surface layer on the graphene layer opposite the foil.

17. The electrical conductor of claim 11, further comprising a surface layer plated on the graphene layer opposite the foil.

18. The electrical conductor of claim 11, wherein the base substrate and layered structure are stamped and formed after the layered structure is deposited on the base substrate.

19. The electrical conductor of claim 11, wherein the base substrate comprises a base and a barrier, the layered structure being deposited on the barrier.

20. The electrical conductor of claim 11, wherein the graphene layer is CVD deposited on one or more surfaces of the foil using an organic compound precursor and heat of sufficient temperature to facilitate graphene growth on the metal compound comprising the foil, the graphene layer being deposited prior to the foil being deposited on the base substrate.
